(19) United States
(12) Patent Application Publication
(10) Pub. No.: US 2023/0073493 A1
(43) Pub. Date: Mar. 9, 2023

(54) BATTERY SYSTEM FOR AN ELECTRIC VEHICLE, METHOD FOR DIAGNOSING A BATTERY SYSTEM, AND ELECTRIC VEHICLE

(71) Applicant: Robert Bosch GmbH, Stuttgart (DE)

(72) Inventors: Chrysanthos Tzivanopoulos, Remseck Am Neckar (DE); Johannes Swoboda, Stuttgart (DE); Thomas Schaedlich, Kornwestheim (DE)

(21) Appl. No.: 17/774,573

(22) PCT Filed: Oct. 2, 2020
(86) PCT No.: PCT/EP2020/077648

§ 371 Date: Nov. 21, 2022

(30) Foreign Application Priority Data
Nov. 6, 2019 (DE) 10 2019 217 056.0

(51) Int. Cl. B60L 50/60; G01R 31/3835; G01R 31/327; G01R 31/396; H02J 7/00

(52) U.S. Cl. CPC B60L 50/60; G01R 31/3835; G01R 31/3275; G01R 31/396; H02J 7/0036; H02J 7/0063

(57) ABSTRACT

The invention relates to a battery system (10) for an electric vehicle, comprising a battery pack (5) having a positive pole (22), a negative pole (21), at least one battery cell (2) and a pack voltage divider (25), and comprising at least one coupling network having a negative terminal (11) and a positive terminal (12), wherein the pack voltage divider (25) comprises a positive pack resistor (RP2) and a positive sub-pack-resistor (RSP2) which are connected to one another in series between the positive pole (22) and a reference point (50), and a negative pack resistor (RP1) and a negative sub-pack-resistor (RSP1) which are connected to one another in series between the negative pole (21) and the reference point (50). The at least one coupling network comprises a coupling voltage divider (15) having a positive coupling resistor (RK2) and a positive sub-coupling-resistor (RSK2) which are connected to one another in series between the positive terminal (12) and the reference point (50), and having a negative coupling resistor (RK1) an a negative sub-coupling-rcsistor (RSK1) which are connected to one another in series between the negative terminal (11) and the reference point (50). The invention also relates to a method for diagnosing a battery system (10) according to the invention, wherein a positive pack voltage (UP2) falling at the positive sub-pack-resistor (RSP2) is measured, a negative pack voltage (UP1) falling at the negative sub-pack-rcsistor (RSP I) is measured, a positive coupling voltage (UK2) falling at the positive sub-coupling-resistor (RSK2) is measured, a negative coupling voltage (UK1) falling at the negative sub-coupling-resistor (RSK1) is measured, and an evaluation of the measured voltages (UP1, UP2, UK1, UK2) is carried out. The invention also relates to an electric vehicle comprising a battery system (10) according to the invention.

### BACKGROUND OF THE INVENTION

The invention relates a battery system for an electric vehicle, comprising a battery pack, which has a positive pole, a negative pole, at least one battery cell and a pack voltage divider, and at least one coupling power supply system, which has a negative terminal and a positive terminal, wherein the pack voltage divider comprises a positive pack resistance and a positive sub-pack resistance, which are connected in series with one another between the positive pole and a reference point, and a negative pack resistance and a negative sub-pack resistance, which are connected in series with one another between the negative pole and the reference point. The invention also relates to a method for diagnosing a battery system according to the invention and to an electric vehicle which comprises a battery system according to the invention.

It is becoming apparent that in the future electrically driven motor vehicles will be used to an increased extent. Rechargeable batteries are used in such electric vehicles, primarily in order to supply electrical energy to electric drive devices. Lithium-ion battery cells are particularly well suited for such applications. Lithium-ion battery cells are characterized by, inter alia, high energy densities, thermal stability and an extremely low level of self-discharge.

A battery pack comprises a plurality of such lithium-ion battery cells which can be connected electrically both in series and in parallel with one another. Such a battery pack has an output voltage in the range of from, for example, 400 V to 800 V, which is present between a positive pole and a negative pole. In addition, a management system is provided which monitors the operation of the battery pack and controls it in such a way that the battery cells are operated safely and sustainably in terms of their life.

In particular, a voltage measurement at the battery pack is required. Owing to the comparatively high output voltage of the battery pack, a direct voltage measurement between the poles of the battery pack is difficult. A measurement of the comparatively high output voltage can take place, for example, by means of DC isolation. It is also known to provide voltage dividers between the poles of a battery pack which comprise a plurality of resistances connected in series. By measuring the sub-voltages in the form of voltage drops across the individual resistances, the output voltage of the battery pack can then be calculated.

Document US 2013/0151175 A1 discloses an arrangement and a method for voltage measurement at a battery. The arrangement in this case comprises a voltage divider having two resistances, wherein a voltage measurement is possible at each of the resistances by means of a corresponding amplifier.

Document CN 204515091 U discloses an arrangement for detecting a voltage in an electric vehicle. The arrangement comprises a voltage divider circuit, which has a plurality of resistances and an operational amplifier.

### SUMMARY OF THE INVENTION

A battery system for an electric vehicle is proposed. The battery system comprises a battery pack, which has a positive pole, a negative pole, at least one battery cell and a pack voltage divider. The battery system also comprises at least one coupling power supply system, which has a negative terminal and a positive terminal.

Preferably, the battery pack has a plurality of battery cells, which are connected in series between the positive pole and the negative pole. The battery cells together produce a system voltage of, for example, 400 V, which is present between the positive pole and the negative pole of the battery pack.

The pack voltage divider comprises a positive pack resistance and a positive sub-pack resistance, which are connected in series with one another between the positive pole and a reference point. The pack voltage divider also comprises a negative pack resistance and a negative sub-pack resistance, which are connected in series with one another between the negative pole and the reference point. The reference point in this case represents a floating reference potential for a voltage measurement.

The positive pack resistance is in this case comparatively greater than the positive sub-pack resistance. The negative pack resistance is in this case comparatively greater than the negative sub-pack resistance. The ratio between the positive pack resistance and the positive sub-pack resistance can be 1000, for example. The ratio between the negative pack resistance and the negative sub-pack resistance can likewise be 1000, for example.

A positive pack voltage in the form of a voltage drop across the positive sub-pack resistance can be measured by a measuring channel. Likewise, a negative pack voltage in the form of a voltage drop across the negative sub-pack resistance can be measured by a measuring channel. Since the positive pack resistance is comparatively greater than the positive sub-pack resistance and the negative pack resistance is comparatively greater than the negative sub-pack resistance, the respective pack voltage can be measured with an adapted scaling. For example, it is possible to scale voltages in a range of from −1000 V to +1000 V to a range of from 0 to 5 V and measure them, wherein a measurement voltage of 2.5 V corresponds to an actual voltage of 0 V. The at least one coupling power supply system is used for connection of the battery system to a vehicle power supply system of the electric vehicle. The at least one coupling power supply system preferably also has a DC-link capacitor, which is connected between the positive terminal and the negative terminal.

According to the invention, the at least one coupling power supply system has a coupling voltage divider. The coupling voltage divider comprises a positive coupling resistance and a positive sub-coupling resistance, which are connected in series with one another between the positive terminal and the reference point. The coupling voltage divider also comprises a negative coupling resistance and a negative sub-coupling resistance, which are connected in series with one another between the negative terminal and the reference point.

The positive coupling resistance is in this case comparatively greater than the positive sub-coupling resistance. The negative coupling resistance is in this case comparatively greater than the negative sub-coupling resistance. The ratio between the positive coupling resistance and the positive sub-coupling resistance can be 1000, for example. The ratio between the negative coupling resistance and the negative sub-coupling resistance can likewise be 1000, for example.

A positive coupling voltage in the form of a voltage drop across the positive sub-coupling resistance can be measured by a measuring channel. Likewise, a negative coupling voltage in the form of a voltage drop across the negative sub-coupling resistance can be measured by a measuring channel.

In accordance with an advantageous configuration of the invention, the battery system comprises a positive pack switch and/or a negative pack switch. The positive pole is connectable to the positive terminal and disconnectable from the positive terminal by means of the positive pack switch. The negative pole is connectable to the negative terminal and disconnectable from the negative terminal by means of the negative pack switch. The pack switches are in the form of electromechanical relays or contactors, for example.

In accordance with a preferred configuration of the invention, a resistance ratio of the pack voltage divider differs from a resistance ratio of the coupling voltage divider. The resistance ratio of the pack voltage divider in this case corresponds to a ratio of a sum of the positive pack resistance and the positive sub-pack resistance to a sum of the negative pack resistance and the negative sub-pack resistance. The resistance ratio of the coupling voltage divider in this case corresponds to a ratio of a sum of the positive coupling resistance and the positive sub-coupling resistance to a sum of the negative coupling resistance and the negative sub-coupling resistance.

Since the positive pack resistance is comparatively greater than the positive sub-pack resistance and the negative pack resistance is comparatively greater than the negative sub-pack resistance, the resistance ratio of the pack voltage divider in this case corresponds approximately to a ratio of the positive pack resistance to the negative pack resistance.

Since the positive coupling resistance is comparatively greater than the positive sub-coupling resistance and the negative coupling resistance is comparatively greater than the negative sub-coupling resistance, the resistance ratio of the coupling voltage divider in this case corresponds approximately to a ratio of the positive coupling resistance to the negative coupling resistance.

In accordance with an advantageous development of the invention, the pack voltage divider comprises a positive measuring switch and/or a negative measuring switch. The positive pack resistance and the positive sub-pack resistance are disconnectable from the positive pole or from the reference point and are connectable to the positive pole or to the reference point by means of the positive measuring switch. The negative pack resistance and the negative sub-pack resistance are disconnectable from the negative pole or from the reference point and are connectable to the negative pole or to the reference point by means of the negative measuring switch. This firstly ensures that it is not possible for discharge of the battery to take place in the switched-off state. Secondly, the measured voltage to be expected is changed by the distortion of the voltage divider.

In accordance with an advantageous configuration of the invention, the battery system further comprises a charging power supply system. The charging power supply system has a positive charging connection, a negative charging connection and a charging voltage divider. The charging voltage divider comprises a positive charging resistance and a positive sub-charging resistance, which are connected in series with one another between the positive charging connection and the reference point. The charging voltage divider also comprises a negative charging resistance and a negative sub-charging resistance, which are connected in series with one another between the negative charging connection and the reference point.

The positive charging resistance is in this case comparatively greater than the positive sub-charging resistance. The negative charging resistance is in this case comparatively greater than the negative sub-charging resistance. The ratio between the positive charging resistance and the positive sub-charging resistance can be 1000, for example. The ratio between the negative charging resistance and the negative sub-charging resistance can likewise be 1000, for example.

A positive charging voltage in the form of a voltage drop across the positive sub-charging resistance can be measured by a measuring channel. Likewise, a negative charging voltage in the form of a voltage drop across the negative sub-charging resistance can be measured by a measuring channel.

In accordance with an advantageous configuration of the invention, the battery system comprises a positive charging switch and/or a negative charging switch. The positive charging connection is connectable to the positive terminal and disconnectable from the positive terminal by means of the positive charging switch. The negative charging connection is connectable to the negative terminal and disconnectable from the negative terminal by means of the negative charging switch. The charging switches are in the form of electromechanical relays or contactors, for example.

In accordance with a preferred configuration of the invention, a resistance ratio of the charging voltage divider differs from a resistance ratio of the pack voltage divider. The resistance ratio of the charging voltage divider in this case corresponds to a ratio of a sum of the positive charging resistance and the positive sub-charging resistance to a sum of the negative charging resistance and the negative sub-charging resistance.

Since the positive charging resistance is comparatively greater than the positive sub-charging resistance and the negative charging resistance is comparatively greater than the negative sub-charging resistance, the resistance ratio of the charging voltage divider in this case corresponds approximately to a ratio of the positive charging resistance to the negative charging resistance.

In accordance with a preferred configuration of the invention, a resistance ratio of the charging voltage divider also differs from a resistance ratio of the coupling voltage divider.

A method for diagnosing a battery system according to the invention is also proposed. In this case, a positive pack voltage in the form of a voltage drop across the positive sub-pack resistance is measured. Likewise, a negative pack voltage in the form of a voltage drop across the negative sub-pack resistance is measured. Likewise, a positive coupling voltage in the form of a voltage drop across the positive sub-coupling resistance is measured. Likewise, a negative coupling voltage in the form of a voltage drop across the negative sub-coupling resistance is measured.

Then, an evaluation of the measured voltages, i.e. in particular the positive pack voltage, the negative pack voltage, the positive coupling voltage and the negative coupling voltage, is performed. By virtue of the evaluation of the measured voltages, in particular the states of pack switches and charging switches, which are in the form of electromechanical relays or contactors, for example, can be identified and evaluated.

Each voltage to be determined between the poles, between the terminals and between the charging connections can be determined by the sum of two measured voltages. Both measuring channels assigned to a voltage divider each measure the voltages reduced by the voltage divider against the floating reference potential of the reference point. In this case, in each case one measuring channel measures a positive potential, and the other measuring channel measures a negative potential. This measurement method is used for each voltage to be measured at the voltage dividers.

Owing to the differing resistance ratios of the pack voltage divider, the charging voltage divider and the coupling voltage divider, the potential of the reference point is distorted by said voltage dividers depending on the switching state of the pack switches and the charging switches.

To be precise, the individual measured positive and negative voltages are changed thereby, but the sums remain the same. In addition, after a successful switching operation, in each case the measured positive and negative voltages of the connected power supply systems and the battery pack are identical. Owing to knowledge of these two principles, conclusions can be drawn on the state of the switches. In particular, is becomes apparent when a switch does not open or close as intended.

A more precise analysis is possible by disconnecting the pack resistances and the sub-pack resistances by means of the measuring switches. If the pack resistances and the sub-pack resistances are individually disconnected when the pack switches and charging switches are open, the potential of the reference point is drawn optionally to the potential of the positive or the negative system voltage. Since, in this case, there is no closed circuit, the measured voltage at the measuring channels assigned to the sub-pack resistances is 0 V.

Should a double insulation fault or adhered contactors at the pack switches or the charging switches occur, this is not the case. In this case, a voltage which is dependent on a bridging resistance of the adhered contactors is measured at the measuring channels assigned to the sub-pack resistances. Conversely, it is possible with this method to determine, in the case of supposedly closed contactors, whether they are actually closed.

An electric vehicle which comprises a battery system according to the invention is also proposed.

When the battery system according to the invention has been installed in an electric vehicle, it has DC isolation with respect to a further low-voltage power supply system in the electric vehicle. Therefore, voltage measurements at the battery system can be performed with DC isolation from the low-voltage power supply system. The reference point to which the voltage dividers are connected in this case represents a floating reference potential for a voltage measurement. By virtue of a voltage adjustment between the power supply systems and the battery pack and a distortion of a reference potential of the reference point, a plausibility check can be performed in respect of the switching state monitoring. Likewise, a diagnosis of the switches is possible irrespective of a voltage present across the power supply system to be connected in each case. In particular there is markedly increased diagnosis coverage for double insulation faults. Particularly robust contactor adhesion diagnosis is possible. For such contactor adhesion diagnosis, in this case no additional auxiliary voltage sources or auxiliary current sources are required. With the method according to the invention, diagnosis of the switching states is possible and potentially defective components can be determined.

### BRIEF DESCRIPTION OF THE DRAWINGS

Embodiments of the invention will be explained in more detail with reference to the drawing and the description below.

In the drawing:

FIG. 1 shows a schematic illustration of a battery system.

### DETAILED DESCRIPTION

In the description below relating to the embodiments of the invention, identical or similar elements are denoted by the same reference symbols, wherein a repeated description of these elements in individual cases has not been provided. The FIGURES represent the subject matter of the invention merely schematically.

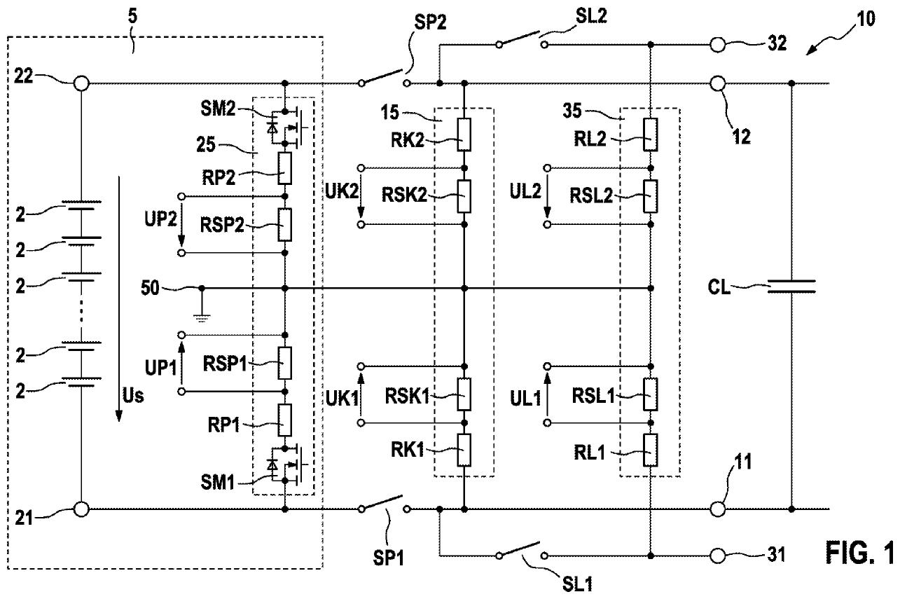

FIG. 1 shows a schematic illustration of a battery system 10 for an electric vehicle. The battery system 10 comprises a battery pack 5, which has a positive pole 22, a negative pole 21 and a plurality of battery cells 2. The battery cells 2 are in this case connected in series between the positive pole 22 and the negative pole 21. A system voltage Us which is provided by the battery cells 2 connected in series is present between the poles 21, 22 of the battery pack 5. The system voltage Us is 400 V, for example.

The battery system 10 also comprises a coupling power supply system. The coupling power supply system has a negative terminal 11 and a positive terminal 12. The coupling power supply system is used in particular for connecting the battery system 10 to a vehicle power supply system of the electric vehicle. The coupling power supply system also has a DC-link capacitor CL, which is connected between the positive terminal 12 and the negative terminal 11.

The battery system 10 comprises a positive pack switch SP2 and a negative pack switch SP1. The positive pole 22 is connectable to the positive terminal 12 and disconnectable from the positive terminal 12 by means of the positive pack switch SP2. The negative pole 21 is connectable to the negative terminal 11 and disconnectable from the negative terminal 11 by means of the negative pack switch SP1. Therefore, the battery pack 5 can be electrically connected to the coupling power supply system and disconnected from the coupling power supply system by means of the pack switches SP1, SP2.

The pack switches SP1, SP2 are in the form of electromechanical relays or contactors, for example. In particular, the two pack switches SP1, SP2 can together form a two-pole relay or contactor.

The battery system 10 further comprises a charging power supply system. The charging power supply system has a positive charging connection 32 and a negative charging connection 31. The charging power supply system is used in particular for charging the battery cells 2 of the battery pack 5 by means of an external charger.

The battery system 10 comprises a positive charging switch SL2 and a negative charging switch SL1. The positive charging connection 32 is connectable to the positive terminal 12 and disconnectable from the positive terminal 12 by means of the positive charging switch SL2. The negative charging connection 31 is connectable to the negative terminal 11 and disconnectable from the negative terminal 11 by means of the negative charging switch SL1. Therefore, the charging power supply system can be electrically connected to the coupling power supply system and disconnected from the coupling power supply system by means of the charging switches SL1, SL2.

The charging switches SL1, SL2 are in the form of electromechanical relays or contactors, for example. In particular, the two charging switches SL1, SL2 can together form a two-pole relay or contactor.

The battery pack 5 has a pack voltage divider 25. The pack voltage divider 25 comprises a positive pack resistance RP2 and a positive sub-pack resistance RSP2 as well as a negative pack resistance RP1 and a negative sub-pack resistance RSP1. The positive pack resistance RP2 and the positive sub-pack resistance RSP2 are connected in series with one another between the positive pole 22 and a reference point 50. The negative pack resistance RP1 and the negative sub-pack resistance RSP1 are connected between the negative pole 21 and the reference point 50.

The pack voltage divider 25 further comprises a positive measuring switch SM2 and a negative measuring switch SM1. The positive measuring switch SM2 is connected in series with the positive pack resistance RP2 and the positive sub-pack resistance RSP2. The negative measuring switch SM1 is connected in series with the negative pack resistance RP1 and the negative sub-pack resistance RSP1. The positive pack resistance RP2 and the positive sub-pack resistance RSP2 are in this case disconnectable from the positive pole 22 and connectable to the positive pole 22 by means of the positive measuring switch SM2. The negative pack resistance RP1 and the negative sub-pack resistance RSP1 are disconnectable from the negative pole 21 and connectable to the negative pole 21 by means of the negative measuring switch SM1.

The measuring switches SM1, SM2 are, for example, in the form of switchable transistors, in particular field-effect transistors, for example MOSFETs.

When the positive measuring switch SM2 is closed, a positive pack voltage UP2 forms as a voltage drop across the positive sub-pack resistance RSP2, and this positive pack voltage UP2 is measured by a measuring channel (not illustrated here). When the negative measuring switch SM1 is closed, a negative pack voltage UP1 forms as a voltage drop across the negative sub-pack resistance RSP1, and this negative pack voltage UP1 is measured by a measuring channel (not illustrated here). The sum of the positive pack voltage UP2 and the negative pack voltage UP1 corresponds, by means of a conversion, to the system voltage Us, which is present between the poles 21, 22 of the battery pack 5. In this case, the conversion is performed taking into consideration the ratio between the positive pack resistance RP2 and the positive sub-pack resistance RSP2 and the ratio between the negative pack resistance RP1 and the negative sub-pack resistance RSP1.

The coupling power supply system has a coupling voltage divider 15. The coupling voltage divider 15 comprises a positive coupling resistance RK2 and a positive sub-coupling resistance RSK2 as well as a negative coupling resistance RK1 and a negative sub-coupling resistance RSK1. The positive coupling resistance RK2 and the positive sub-coupling resistance RSK2 are connected in series with one another between the positive terminal 12 and the reference point 50. The negative coupling resistance RK1 and the negative sub-coupling resistance RSK1 are connected in series with one another between the negative terminal 11 and the reference point 50.

A positive coupling voltage UK2 forms as a voltage drop across the positive sub-coupling resistance RSK2, and this positive coupling voltage UK2 is measured by a measuring channel (not illustrated here). A negative coupling voltage UK1 forms as a voltage drop across the negative sub-coupling resistance RSK1, and this negative coupling voltage UK1 is measured by a measuring channel (not illustrated here). The sum of the positive coupling voltage UK2 and the negative coupling voltage UK1 corresponds, by means of a conversion, to a voltage which is present between the terminals 11, 12. In this case, the conversion is performed taking into consideration the ratio between the positive coupling resistance RK2 and the positive sub-coupling resistance RSK2 and the ratio between the negative coupling resistance RK1 and the negative sub-coupling resistance RSK1.

When the pack switches SP1, SP2 are closed, the voltage which is present between the terminals 11, 12 corresponds to the system voltage Us, which is present between the poles 21, 22 of the battery pack 5.

The charging power supply system has a charging voltage divider 35. The charging voltage divider 35 comprises a positive charging resistance RL2 and a positive sub-charging resistance RSL2 as well as a negative charging resistance RL1 and a negative sub-charging resistance RSL1. The positive charging resistance RL2 and the positive sub-charging resistance RSL2 are connected in series with one another between the positive charging connection 32 and the reference point 50. The negative charging resistance RL1 and the negative sub-charging resistance RSL1 are connected in series with one another between the negative charging connection 31 and the reference point 50.

A positive charging voltage UL2 forms as a voltage drop across the positive sub-charging resistance RSL2, and this positive charging voltage UL2 is measured by a measuring channel (not illustrated here). A negative charging voltage UL1 forms as a voltage drop across the negative sub-charging resistance RSL1, and this negative charging voltage UL1 is measured by a measuring channel (not illustrated here). The sum of the positive charging voltage UL2 and the negative charging voltage UL1 corresponds, by means of a conversion, to a voltage which is present between the charging connections 31, 32. In this case, the conversion is performed taking into consideration the ratio between the positive charging resistance RL2 and the positive sub-charging resistance RSL2 and the ratio between the negative charging resistance RL1 and the negative sub-charging resistance RSL1.

When the pack switches SP1, SP2 and the charging switches SL1, SL2 are closed, the voltage which is present between the charging connections 31, 32 corresponds to the system voltage Us, which is present between the poles 21, 22 of the battery pack 5.

The positive pack resistance RP2 in this case has a value of 5 MΩ. The positive sub-pack resistance RSP2 in this case has a value of 50 kΩ. The negative pack resistance RP1 in this case has a value of 5 MΩ. The negative sub-pack resistance RSP1 in this case has a value of 50 kΩ. A resistance ratio of the pack voltage divider 25 approximately corresponds to a ratio of the positive pack resistance RP2 to the negative pack resistance RP1. In this case, the resistance ratio of the pack voltage divider 25 is therefore:

RP2/RP1=5/5=1

The positive coupling resistance RK2 in this case has a value of 7 MΩ. The positive sub-coupling resistance RSK2 in this case has a value of 70 kΩ. The negative coupling resistance RK1 in this case has a value of 3 MΩ. The negative sub-coupling resistance RSK1 in this case has a value of 30 kΩ. A resistance ratio of the coupling voltage divider 15 approximately corresponds to a ratio of the positive coupling resistance RK2 to the negative coupling resistance RK1. In this case, the resistance ratio of the coupling voltage divider 15 is therefore:

RK2/RK1≈7/3 2.333

The positive charging resistance RL2 in this case has a value of 6 MΩ. The positive sub-charging resistance RSL2 in this case has a value of 60 kΩ. The negative charging resistance RL1 in this case has a value of 4 MΩ. The negative sub-charging resistance RSL1 in this case has a value of 40 kΩ. A resistance ratio of the charging voltage divider 35 approximately corresponds to a ratio of the positive charging resistance RL2 to the negative charging resistance RL1. In this case, the resistance ratio of the charging voltage divider 35 is therefore:

RL2/RL1=6/4=1.5

The resistance ratio of the pack voltage divider 25, the resistance ratio of the coupling voltage divider 15 and the resistance ratio of the charging voltage divider 35 therefore each differ from one another.

The invention is not restricted to the exemplary embodiments described here and the aspects highlighted therein. Rather, a multiplicity of modifications which are within the scope of a person skilled in the art is possible within the scope set forth in the claims.

1. A battery system (10) for an electric vehicle, comprising
a battery pack (5), which has a positive pole (22), a negative pole (21), at least one battery cell (2) and a pack voltage divider (25), and
at least one coupling power supply system, which has a negative terminal (11) and a positive terminal (12), wherein
the pack voltage divider (25) comprises
a positive pack resistance (RP2) and a positive sub-pack resistance (RSP2), which are connected in series with one another between the positive pole (22) and a reference point (50), and
a negative pack resistance (RP1) and a negative sub-pack resistance (RSP1), which are connected in series with one another between the negative pole (21) and the reference point (50),
characterized in that
the at least one coupling power supply system has
a coupling voltage divider (15), which comprises
a positive coupling resistance (RK2) and a positive sub-coupling resistance (RSK2), which are connected in series with one another between the positive terminal (12) and the reference point (50), and
a negative coupling resistance (RK1) and a negative sub-coupling resistance (RSK1), which are connected in series with one another between the negative terminal (11) and the reference point (50).

2. The battery system (10) as claimed in claim 1, characterized in that the positive pole (22) is connectable to the positive terminal (12) by means of a positive pack switch (SP2), and/or in that
the negative pole (21) is connectable to the negative terminal (11) by means of a negative pack switch (SP1).

3. The battery system (10) as claimed in either of the preceding claims, characterized in that
a resistance ratio of the pack voltage divider (25) differs from a resistance ratio of the coupling voltage divider (15).

4. The battery system (10) as claimed in one of the preceding claims, characterized in that
the pack voltage divider (25) comprises
a positive measuring switch (SM2), by means of which the positive pack resistance (RP2) and the positive sub-pack resistance (RSP2) are disconnectable from the positive pole (22) or the reference point (50), and/or
a negative measuring switch (SM1), by means of which the negative pack resistance (RP1) and the negative sub-pack resistance (RSP1) are disconnectable from the negative pole (21) or the reference point (50).

5. The battery system (10) as claimed in one of the preceding claims, further comprising
a charging power supply system, which has a positive charging connection (32), a negative charging connection (31) and a charging voltage divider (35), wherein
the charging voltage divider (35) comprises
a positive charging resistance (RL2) and a positive sub-charging resistance (RSL2), which are connected in series with one another between the positive charging connection (32) and the reference point (50), and
a negative charging resistance (RL1) and a negative sub-charging resistance (RSL1), which are connected in series with one another between the negative charging connection (31) and the reference point (50).

6. The battery system (10) as claimed in claim 5, characterized in that
the positive charging connection (32) is connectable to the positive terminal (12) by means of a positive charging switch (SL2), and/or in that
the negative charging connection (31) is connectable to the negative terminal (11) by means of a negative charging switch (SL1).

7. The battery system (10) as claimed in either of claims 5 to 6, characterized in that
a resistance ratio of the charging voltage divider (35) differs from a resistance ratio of the pack voltage divider (25).

8. The battery system (10) as claimed in one of claims 5 to 7, characterized in that
a resistance ratio of the charging voltage divider (35) differs from a resistance ratio of the coupling voltage divider (15).

9. A method for diagnosing a battery system (10) as claimed in one of the preceding claims, wherein
a positive pack voltage (UP2) in the form of a voltage drop across the positive sub-pack resistance (RSP2) is measured,
a negative pack voltage (UP1) in the form of a voltage drop across the negative sub-pack resistance (RSP1) is measured,
a positive coupling voltage (UK2) in the form of a voltage drop across the positive sub-coupling resistance (RSK2) is measured,
a negative coupling voltage (UK1) in the form of a voltage drop across the negative sub-coupling resistance (RSK1) is measured, and
an evaluation of the measured voltages (UP1, UP2, UK1, UK1) is performed.

10. An electric vehicle, comprising a battery system (10) as claimed in one of claims 1 to 8.
